(19) United States
(12) Patent Application Publication
(10) Pub. No.: US 2025/0274220 A1
(43) Pub. Date: Aug. 28, 2025

(54) SYSTEM AND METHOD FOR IMPLEMENTING A COMMON PROCESSING CHAIN FOR PBCH AND PDCCH CHANNELS

(71) Applicant: JIO PLATFORMS LIMITED, Ahmedabad, Gujarat (IN)

(72) Inventors: Vinod Kumar SINGH, Navi Mumbai, Maharashtra (IN); Veera Sai Satyanarayana Prasad MARNI, Navi Mumbai, Maharashtra (IN); Abhilash KUMAR, Palava City, Mahashatra (IN); Aayush BHATNAGAR, Navi Mumbai, Maharashtra (IN); Pradeep BHATNAGAR, Navi Mumbai, Maharashtra (IN)

(73) Assignee: JIO PLATFORMS LIMITED, Ahmedabad, Gujarat (IN)

(21) Appl. No.: 18/878,993

(22) PCT Filed: Sep. 1, 2023
(86) PCT No.: PCT/IB2023/058657

§ 371 Date: Dec. 26, 2024

(30) Foreign Application Priority Data
Sep. 2, 2022 (IN) 202221050307

(51) Int. Cl. H04L 1/00; H04L 27/26; H04W 72/21

(52) U.S. Cl. CPC H04L 1/0067; H04L 27/2607; H04W 72/21

(57) ABSTRACT

The present disclosure relates to a system and a method for processing data in control channels. The system provides control data including a plurality of bits from the control channels to a cyclic redundancy check (CRC) block. The system determines if the plurality of bits corresponds to broadcast channel (BCH) data or downlink control information (DCI) data, and interleaves the plurality of bits if the plurality of bits corresponds to the BCH data, or bypasses interleaving of the plurality of bits if the plurality of bits corresponds to the DCI data. The system performs rate matching of the plurality of bits, and determines a length of a plurality of rate matched bits by setting an aggregation level for the control channels. The system performs scrambling operation on the plurality of rate matched bits, and modulates the plurality of rate matched bits based on scrambling operation outputs.

### RESERVATION OF RIGHTS

A portion of the disclosure of this patent document contains material, which is subject to intellectual property rights such as, but are not limited to, copyright, design, trademark, Integrated Circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF DISCLOSURE

The present disclosure relates to telecommunication systems, and specifically to a system and method for implementing a common unified processing chain for one or more control channels such as 5th Generation (5G) New Radio (NR) Physical Broadcast Channel (PBCH) and Physical Downlink Control Channel (PDCCH).

### BACKGROUND OF DISCLOSURE

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Physical Broadcast Channel (PBCH) and Physical Downlink Control Channel (PDCCH) are control channels defined in 5th Generation (5G) New Radio (NR). The PBCH is responsible for achieving synchronization in downlink and carrying a Master Information Block (MIB), and the PDCCH is responsible for carrying downlink and uplink scheduling information using different Downlink Control Information (DCI) types. While both the PBCH and PDCCH chains offer different functionality, their layer 1 processing is similar by design. Both the PBCH and the PDCCH channels use a polar code for channel coding. Further, a rate matching procedure defined in 3rd Generation Partnership Project (3GPP) is also specific to polar encoded data. Therefore, both the PBCH and PDCCH chains uses same rate matching procedure defined for the polar encoded data. Both the PBCH and PDCCH chains are further scrambled using gold sequences and are Quadrature Phase Shift Keying (QPSK) modulated.

Although both the PBCH and the PDCCH have commonalities as mentioned above, they operate on different sets of control inputs. Besides, all sub-blocks of a processing chain (namely polar, rate matching, and scrambling) also have corresponding chain specific customizations. Due to these changes, conventionally, the PBCH and the PDCCH chains are implemented separately.

There is, therefore, a need in the art to provide an improved system and method that implements a unified common processing chain where each physical layer 1 (L1) sub-block is designed to process both PBCH and PDCCH Packet Data Units (PDUs) seamlessly.

### OBJECTS OF THE PRESENT DISCLOSURE

Some of the objects of the present disclosure, which at least one embodiment herein satisfies are as listed herein below.

It is an object of the present disclosure to provide a system and a method that implements a unified common processing chain where each physical layer 1 (L1) sub-block is designed to process both Physical Broadcast Channel (PBCH) and Physical Downlink Control Channel (PDCCH) Packet Data Units (PDUs) seamlessly.

It is an object of the present disclosure to provide a system and a method to modify control data received by L1 sub-blocks from a Layer 2 (L2) over a L1-L2 interface.

It is an object of the present disclosure to provide a system and a method to optimize resource utilization during channel coding.

It is an object of the present disclosure to provide a system and a method to modify control parameters in such a way that a same set of sub-blocks support processing of both the PBCH and PDCCH PDUs, thereby ensuring efficient resource utilization.

It is an object of the present disclosure to provide a system and a method to reduce processing time of the PBCH PDUs and the PDCCH PDUs.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure relates to a system for processing data in one or more control channels using a unified processing chain. The system includes one or more processors, and a memory operatively coupled to the one or more processors, where the memory includes processor-executable instructions, which on execution, cause the one or more processors to provide control data including a plurality of bits from the one or more control channels to a cyclic redundancy check (CRC) engine, determine if the plurality of bits of the control data corresponds to a broadcast channel (BCH) data or a downlink control information (DCI) data based on one or more control parameters corresponding to the one or more control channels, perform one of: interleave the plurality of bits if the plurality of bits corresponds to the BCH data, or bypass interleaving of the plurality of bits if the plurality of bits corresponds to the DCI data, perform rate matching of the plurality of bits to ensure that the plurality of bits corresponds to a capacity of the one or more control channels based on the determination, determine a length of the plurality of rate matched bits by setting an aggregation level for the one or more control channels, perform scrambling operation on the plurality of rate matched bits based on the length of the plurality of rate matched bits, and modulate the plurality of rate matched bits based on outputs of the scrambling operation.

In an embodiment, the one or more control channels may be Physical Broadcast Channel (PBCH) and Physical Downlink Control Channel (PDCCH).

In an embodiment, the one or more control parameters corresponding to the one or more control channels may include at least one of a payload size field and a channel indicator field.

In an embodiment, the memory includes processor-executable instructions, which on execution, may cause the one or more processors to determine a length of the control data, and distinguish the control data corresponding to each control channel of the one or more control channels for appending correct bit sequence in the CRC engine based on the channel indicator field.

In an embodiment, the one or more processors may append 24 zeroes to an incoming payload of the control data if the channel indicator field is set to 0 indicating the BCH data, and append 24 ones to the incoming payload of the control data if the channel indicator field is set to 1 indicating the DCI data.

In an embodiment, the memory includes processor-executable instructions, which on execution, may cause the one or more processors to encode the plurality of bits of the control data prior to performing the rate matching.

In an embodiment, the one or more processors may perform the rate matching of the plurality of bits based on a payload size of the control data and the aggregation level of the one or more control channels, where the aggregation level for the BCH data may be set to 8.

In an embodiment, the one or more processors may perform the scrambling operation on the plurality of rate matched bits using at least one of a Radio Network Temporary Identifier (RNTI), a Physical Cell Identity (PCI), a Synchronization Signal Block (SSB) index, and the aggregation level.

In an embodiment, the one or more processors may perform the scrambling operation on the plurality of rate matched bits by determining a pseudo-random (PN) sequence length of the plurality of rate matched bits using the aggregation level.

In another aspect, the present disclosure relates to a method for processing data in one or more control channels using a unified processing chain. The method includes providing, by a processor associated with a system, control data including a plurality of bits from the one or more control channels to a cyclic redundancy check (CRC) engine, determining, by the processor, if the plurality of bits of the control data corresponds to a broadcast channel (BCH) data or a downlink control information (DCI) data based on one or more control parameters corresponding to the one or more control channels, performing, by the processor, one of: interleaving the plurality of bits if the plurality of bits corresponds to the BCH data, or bypassing interleaving of the plurality of bits if the plurality of bits corresponds to the DCI data, performing, by the processor, rate matching of the plurality of bits to ensure that the plurality of bits corresponds to a capacity of the one or more control channels based on the determination, determining, by the processor, a length of the plurality of rate matched bits by setting an aggregation level for the one or more control channels, performing, by the processor, scrambling operation on the plurality of rate matched bits based on the length of the plurality of rate matched bits, and modulating, by the processor, the one or more channels based on outputs of the scrambling operation.

In an embodiment, the one or more control parameters corresponding to the one or more control channels may include at least one of a payload size field and a channel indicator field.

In an embodiment, the method may include determining, by the processor, a length of the control data, and distinguishing, by the processor, the control data corresponding to each control channel of the one or more control channels for appending correct bit sequence in the CRC engine based on the channel indicator field.

In an embodiment, the method may include encoding, by the processor, the plurality of bits of the control data prior to performing the rate matching.

In an embodiment, the method may include performing, by the processor, the rate matching of the plurality of bits based on a payload size of the control data and the aggregation level of the one or more control channels, where the aggregation level for the BCH data may be set to 8.

In an embodiment, performing, by the processor, the scrambling operation on the plurality of rate matched bits may include using at least one of a Radio Network Temporary Identifier (RNTI), a Physical Cell Identity (PCI), a Synchronization Signal Block (SSB) index, and the aggregation level.

In an embodiment, performing, by the processor, the scrambling operation on the plurality of rate matched bits may include determining a pseudo-random (PN) sequence length of the plurality of rate matched bits using the aggregation level.

In another aspect, the present disclosure relates to a user equipment. The user equipment includes one or more processors, and a memory operatively coupled to the one or more processors, wherein the memory includes processor-executable instructions, which on execution, cause the one or more processors to receive a plurality of modulated bits of control data from a system, demodulate the plurality of received bits, perform descrambling operation on the plurality of demodulated bits, perform de-rate matching of the plurality of demodulated bits based on outputs of the descrambling operation, determine if the plurality of de-rate matched bits corresponds to a broadcast channel (BCH) data or a downlink control information (DCI) data based on one or more control parameters corresponding to one or more control channels, perform one of de-interleave the plurality of de-rate matched bits if the plurality of received bits corresponds to the BCH data, and bypass de-interleaving of the plurality of de-rate matched bits if the plurality of received bits corresponds to the DCI data, decode the plurality of de-rate matched bits based on the determination, and provide the plurality of decoded bits to a cyclic redundancy check (CRC) engine.

In an aspect, the present disclosure relates to a non-transitory computer-readable medium including processor-executable instructions that cause a processor to provide control data including a plurality of bits from one or more control channels to a cyclic redundancy check (CRC) engine, determine if the plurality of bits of the control data corresponds to a broadcast channel (BCH) data or a downlink control information (DCI) data based on one or more control parameters corresponding to the one or more control channels, perform one of: interleave the plurality of bits if the plurality of bits corresponds to the BCH data, or bypass interleaving of the plurality of bits if the plurality of bits corresponds to the DCI data, perform rate matching of the plurality of bits to ensure that the plurality of bits corresponds to a capacity of the one or more control channels based on the determination, determine a length of the plurality of rate matched bits by setting an aggregation level for the one or more control channels, perform scrambling operation on the plurality of rate matched bits based on the length of the plurality of rate matched bits, and modulate the plurality of rate matched bits based on outputs of the scrambling operation.

### BRIEF DESCRIPTION OF THE DRAWINGS

The accompanying drawings, which are incorporated herein, and constitute a part of this invention, illustrate exemplary embodiments of the disclosed methods and systems in which like reference numerals refer to the same parts throughout the different drawings. Components in the drawings are not necessarily to scale, emphasis instead being placed upon clearly illustrating the principles of the present invention. Some drawings may indicate the components using block diagrams and may not represent the internal circuitry of each component. It will be appreciated by those skilled in the art that invention of such drawings includes the invention of electrical components, electronic components or circuitry commonly used to implement such components.

The diagrams are for illustration only, which thus is not a limitation of the present disclosure, and wherein:

FIG. 1 illustrates an exemplary representation (100) for implementing conventional method of resource allocation for Synchronization Signal Block (SSB).

FIG. 2 illustrates an exemplary representation (200) of conventional physical layer processing sub-blocks of a Physical Broadcast Channel (PBCH) chain.

FIG. 3 illustrates an exemplary representation (300) of all sub-blocks involved in conventional Physical Downlink Control Channel (PDCCH) processing.

FIG. 4 illustrates an exemplary network architecture (400) in which or with which embodiments of the present disclosure may be implemented.

FIG. 5A illustrates an exemplary block diagram (500A) of a proposed system (408), in accordance with an embodiment of the present disclosure.

FIG. 5B illustrates an exemplary block diagram (500B) of sub-blocks of a system processing engine (508), in accordance with an embodiment of the present disclosure.

FIG. 6 illustrates an exemplary computer system (600) in which or with which embodiments of the present disclosure may be utilized in accordance with embodiments of the present disclosure.

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Physical Broadcast Channel (PBCH) and Physical Downlink Control Channel (PDCCH) are control channels defined in 5th Generation (5G) New Radio (NR). PBCH achieves synchronization in downlink and carries Master Information Block (MIB). PDCCH carries downlink and uplink scheduling information using different Downlink Control Information (DCI) types.

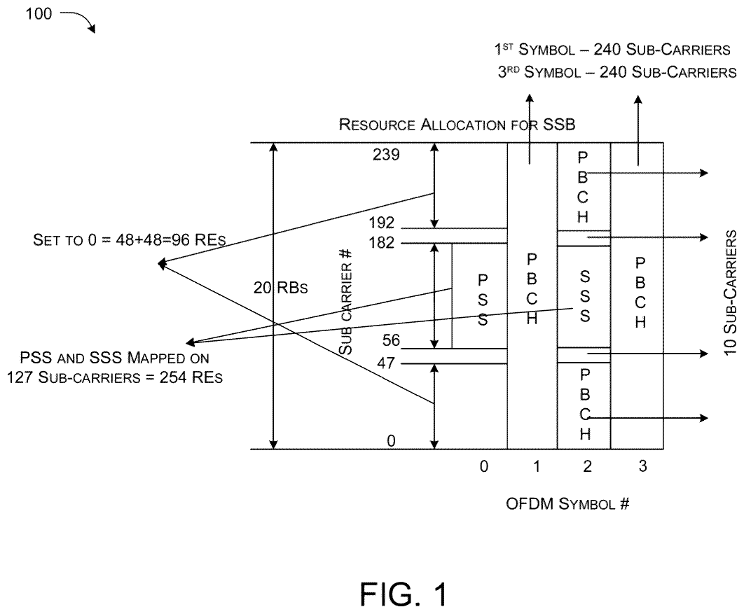

With respect to FIG. 1 which illustrates an exemplary representation (100) for implementing conventional method of resource allocation for Synchronization Signal Block (SSB), the PBCH may carry critical information required for further system access (e.g., to acquire System Information Block 1 (SIB1)). The PBCH may occupy two full Orthogonal Frequency-Division Multiplexing (OFDM) symbols (second and fourth) spanning 240 subcarriers and in a third OFDM symbol spanning 48 subcarriers below and above secondary synchronization signal (SSS). This results in the PBCH (including PBCH Demodulation Reference Signal (DMRS)) occupying 576 subcarriers across the three OFDM symbols.

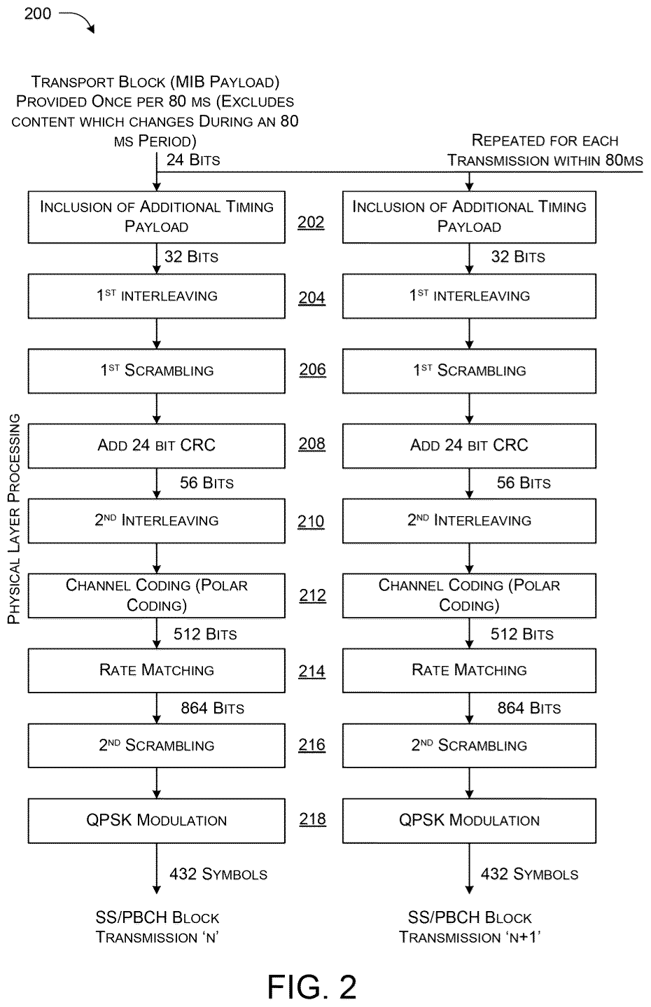

FIG. 2 illustrates an exemplary representation (200) of conventional physical layer processing sub-blocks of the PBCH chain. With respect to FIG. 2, a Medium Access Control (MAC) layer may provide a physical layer with a Broadcast Channel (BCH) transport block. The BCH transport block may be a MIB having a size of 24 bits. The MIB may include timing information in terms of 6 Most Significant Bits (MSB) of a System Frame Number (SFN). 4 Least Significant Bits (LSB) may not be included within the MIB. This means that content of the MIB changes every 160 ms, because the SFN increments every 10 ms.

At 202, the physical layer of a base station may attach additional information to the MIB before being processed for transmission across an air interface. The additional information may include 4 LSB of the SFN. Adding the 8 bits at the physical layer may reduce a rate at which a Radio Resource Control (RRC) layer has to update the MIB. In case of frequency range 1 (450 MHz to 6 GHz), the physical layer may also include information regarding a sub-carrier offset between Synchronization Signals (SS)/PBCH block and a main resource block grid.

Once the 8 bits of additional information are added to the transport block, a first stage of interleaving is applied, at 204. The interleaving may be performed to change an order of the bits within a packet. The interleaving may be done using a fixed re-ordering pattern which remains constant for all the PBCH transmissions. In addition, the interleaving may be used to control order of the bits being fed into a channel coding block. Polar coding may provide a non-uniform reliability for a set of input bits. The interleaving may be used to control which bits are transferred with highest reliability and which bits are transferred with a lower reliability. In this case, the timing information bits (10 bits for the SFN; 1 bit for a half frame index; 3 bits for the SS/PBCH block index) may be mapped into positions with lowest reliability.

A first stage of scrambling may be applied after the first stage of interleaving, at 206. The following timing information bits may be excluded from a scrambling procedure: 2^{nd} and 3^{rd} LSB of the SFN, 1 bit half frame index, and 1^{st}, 2^{nd}, and 3^{rd} LSB of a SS/PBCH block index.

The scrambling procedure may use a pseudo random sequence to randomly change some bits from ‘1’ to ‘0’ and other bits from ‘0’ to ‘1’. The order of the bits may not be changed. A scrambling sequence may be initialized using a Physical layer Cell Identity (PCI) so neighbouring cells may use different scrambling sequences. The scrambling procedure may be performed to randomize bit stream, and thus, randomize inter-cell interference experienced by neighbouring cells. Impact of inter-cell interference may be reduced if the interference appears random (similar to thermal noise). Randomization of the bit stream may be improved by giving the scrambling sequence a time dependency. The 2^{nd} and 3^{rd} LSB of the SFN may be used to determine which part of the scrambling sequence is used for each PBCH transmission.

Further, at 208, 24 Cyclic Redundancy Check (CRC) bits may be calculated from a set of 32 bits and may be subsequently concatenated to generate a resultant packet size of 56 bits. The CRC bits may be used at a User Equipment (UE) receiver to detect whether or not there are any bit errors within the decoded packet.

At 210, a second stage of interleaving may be performed just prior to channel coding. The two interleaving stages may be combined to move the timing information bits into least reliable positions. Similar to the first stage of interleaving, the bit positions may be changed to determine which parts of the payload are transmitted with the highest reliability and which parts of the payload are transmitted with the lower reliability. The second stage of interleaving may move the CRC bits into the positions with the highest reliability, i.e., the CRC bits may be treated as the most important bits.

At 212, polar coding may be performed for PBCH channel coding. The polar coding may increase a number of bits from 56 to 512, i.e., a coding rate of 56/512=0.11 may be achieved. Further, rate matching may be applied to ensure that the number of bits corresponds to a capacity of the physical channel, at 214. Each transmission of the PBCH may be allocated with 432 resource elements. The PBCH may always be transmitted using a Quadrature Phase Shift Keying (QPSK) modulation, at 218, so the 432 resource elements may be able to accommodate 432 QPSK symbols which transfer 864 bits of information. The rate matching procedure may be repeated to generate 864 bits from a set of 512 polar coded bits.

Furthermore, a second phase of the scrambling may be applied before modulation, at 216. The scrambling sequence may be initialized using the PCI. The section of the scrambling sequence which is used for the scrambling may be dependent upon: (i) 2 least significant bits of the SS/PBCH block index, for operating bands below 3 GHz, and (ii) 3 least significant bits of the SS/PBCH block index, for operating bands above 3 GHz.

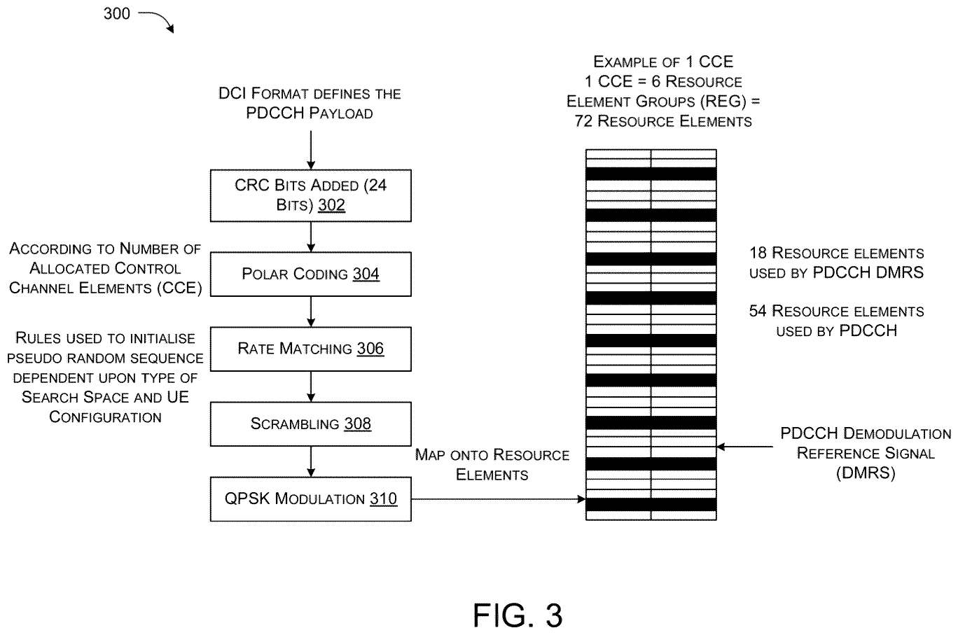

FIG. 3 illustrates an exemplary flow diagram (300) of all sub blocks involved in conventional PDCCH processing. The PDCCH may be used to transfer DCI. The PDCCH may correspond to physical layer signalling from layer 1, in contrast to RRC signalling from layer 3 or use of MAC control elements from layer 2.

With respect to FIG. 3, at 302, the CRC bits may be added to a DCI payload received from L2, which allows error detection at a UE. The PDCCH may not have any mechanism which allows the UE to directly indicate successful/unsuccessful reception. Instead, a base station may have to rely upon indirect mechanisms, e.g., if the base station uses the PDCCH to allocate uplink resources on the PUSCH but if the base station does not receive a Physical Uplink Shared Channel (PUSCH) transmission, then the base station may deduce that the UE failed to receive the PDCCH. Next, a set of 24 CRC bits may be calculated from the PDCCH payload. The CRC bits may be scrambled using a relevant Radio Network Temporary Identifier (RNTI). Scrambling may change some bits from ‘1’ to ‘0’ and other bits from ‘0’ to ‘1’. However, the order of the bits may not be changed.

At 304, channel coding may be applied after the CRC bits have been added. Polar coding may be used as a channel coding solution for the PDCCH. The coding rate may depend upon an aggregation level allocated to the PDCCH, i.e., the number of Control Channel Elements (CCE). At 306, rate matching may be applied after channel coding to ensure that the number of bits matches capacity of the resource elements available to the PDCCH after accounting for a DMRS. A single CCE may accommodate 108 bits after accounting for the DMRS. The rate matching may also include an interleaving operation to change an order of the transmitted bits and present a set of aggregation levels specified by the 3^{rd} Generation Partnership Project (3GPP). The number of resource elements may be required to accommodate both the PDCCH and the PDCCH DMRS, i.e., not all resource elements are available to transfer the payload.

The resultant bits may then be scrambled using a pseudo random sequence, at 308. Initialization of the pseudo random sequence may depend upon a type of search space, and determination on whether or not the UE have been configured with a pdcch-DMRS-ScramblingID. If a common search space is used, then the pseudo random sequence may be initialized using the PCI which has been allocated to the cell. If a UE's specific search space is used and the UE has been configured with the pdcch-DMRS-ScramblingID, then the pseudo random sequence may be initialized using a combination of a Cell RNTI (C-RNTI) and the pdcch-DMRS-ScramblingID. If the UE specific search space is used but the UE has not been configured with the pdcch-DMRS-ScramblingID, then the pseudo random sequence may be initialized using the PCI which has been allocated to the cell.

At 310, QPSK modulation may be applied to generate the set of modulation symbols which are mapped onto the allocated resource elements.

The present disclosure provides a system and a method to implement a unified common processing chain where each physical layer 1 (L1) sub-block is designed to process both PBCH and PDCCH Packet Data Units (PDUs) seamlessly. The system modifies control data received by the L1 sub-blocks from a Layer 2 (L2) over a L1-L2 interface. The system modifies all the sub-blocks and control parameters in such a way that a same set of sub-blocks support processing of both the PBCH and PDCCH PDUs, thereby ensuring efficient resource utilization. The system reduces processing time of the PBCH PDUs and the PDCCH PDUs.

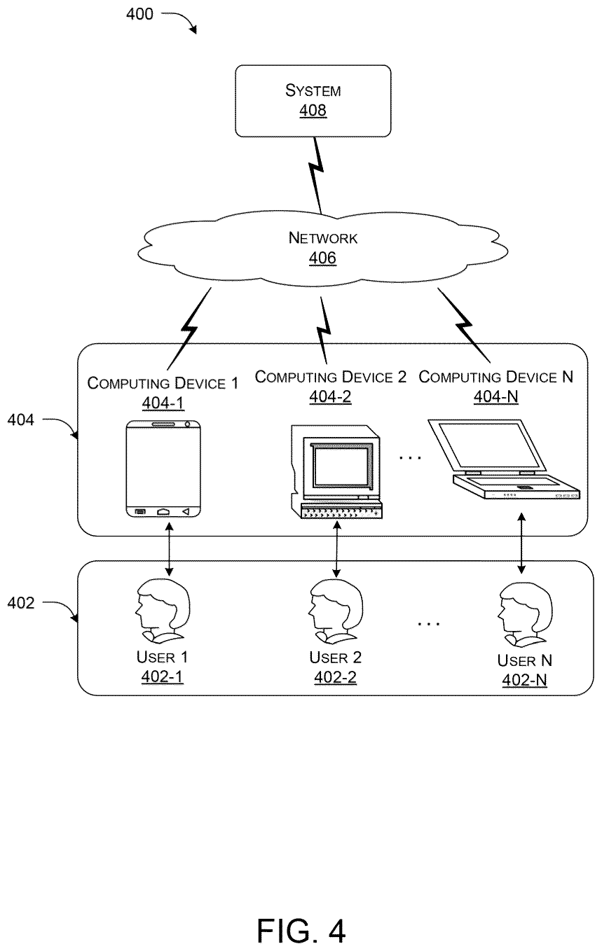

Various embodiments of the present disclosure will be explained in detail with reference to FIGS. 4-6.

FIG. 4 illustrates an exemplary network architecture (400) in which or with which a proposed system may be implemented.

As illustrated in FIG. 4, by way of an example and not by limitation, the exemplary network architecture (400) may include a plurality of computing devices (404-1, 404-2 . . . 404-N), which may be individually referred as the computing device (404) and collectively referred as the computing devices (404). The plurality of computing devices (404) may include, but not be limited to, scanners such as cameras, webcams, scanning units, and the like configured to send a request or an input including a plurality of control parameters to a system (408). The control parameters may include, but not limited to, a length of control data, a Radio Network Temporary Identifier (RNTI), a Physical Cell Identity (PCI), a Synchronization Signal Block (SSB) index, and an aggregation level of one or more channels.

In an embodiment, the computing device (404) may include smart devices operating in a smart environment, for example, an Internet of Things (IoT) system. In such an embodiment, the computing device (404) may include, but is not limited to, smart phones, smart watches, smart sensors (e.g., mechanical, thermal, electrical, magnetic, etc.), networked appliances, networked peripheral devices, networked lighting system, communication devices, networked vehicle accessories, networked vehicular devices, smart accessories, tablets, smart television (TV), computers, smart security system, smart home system, other devices for monitoring or interacting with or for the users and/or entities, or any combination thereof.

A person of ordinary skill in the art will appreciate that the computing device or a user equipment (404) may include, but is not limited to, intelligent, multi-sensing, network-connected devices, that may integrate seamlessly with each other and/or with a central server or a cloud-computing system or any other device that is network-connected.

In an embodiment, the computing device (404) may include, but is not limited to, a handheld wireless communication device (e.g., a mobile phone, a smart phone, a phablet device, and so on), a wearable computer device (e.g., a head-mounted display computer device, a head-mounted camera device, a wristwatch computer device, and so on), a Global Positioning System (GPS) device, a laptop computer, a tablet computer, or another type of portable computer, a media playing device, a portable gaming system, and/or any other type of computer device with wireless communication capabilities, and the like. In an embodiment, the computing device (404) may include, but is not limited to, any electrical, electronic, electro-mechanical, or an equipment, or a combination of one or more of the above devices such as virtual reality (VR) devices, augmented reality (AR) devices, laptop, a general-purpose computer, desktop, personal digital assistant, tablet computer, mainframe computer, or any other computing device, wherein the computing device (104) may include one or more in-built or externally coupled accessories including, but not limited to, a visual aid device such as a camera, an audio aid, a microphone, a keyboard, and input devices for receiving input from the user or the entity such as touch pad, touch enabled screen, electronic pen, and the like. A person of ordinary skill in the art may appreciate that the computing device (404) may not be restricted to the mentioned devices and various other devices may be used.

In an exemplary embodiment, the computing device/user equipment (404) may communicate with the system (408) through a network (406). The network (406) may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. The network (406) may include, by way of example but not limitation, one or more of: a wireless network, a wired network, an internet, an intranet, a public network, a private network, a packet-switched network, a circuit-switched network, an ad hoc network, an infrastructure network, a public-switched telephone network (PSTN), a cable network, a cellular network, a satellite network, a fiber optic network, some combination thereof.

In an embodiment, the system (408) may process data in one or more control channels. In an embodiment, the system (408) may provide control data including a plurality of bits from L2 containing BCH payload/DCI payload size field and a channel indicator field, of the one or more control channels into a CRC block. The system (408) may determine if the plurality of bits of the control data corresponds to BCH data or DCI data, and may interleave the plurality of bits if the plurality of bits corresponds to the BCH data, or bypass interleaving of the plurality of bits if the plurality of bits corresponds to the DCI data.

The system (408) may perform rate matching of the plurality of bits to ensure that the plurality of bits corresponds to a capacity of the one or more control channels based on the determination.

The system (408) may determine length of a plurality of rate matched bits by setting an aggregation level for the one or more control channels, and perform bitwise operation on the plurality of rate matched bits based on the length of the plurality of rate matched bits. Further, the system (408) may modulate the one or more channels based on bitwise operation outputs using a QPSK modulator.

Although FIG. 4 shows exemplary components of the network architecture (400), in other embodiments, the network architecture (400) may include fewer components, different components, differently arranged components, or additional functional components than depicted in FIG. 4. Additionally, or alternatively, one or more components of the network architecture (400) may perform functions described as being performed by one or more other components of the network architecture (400).

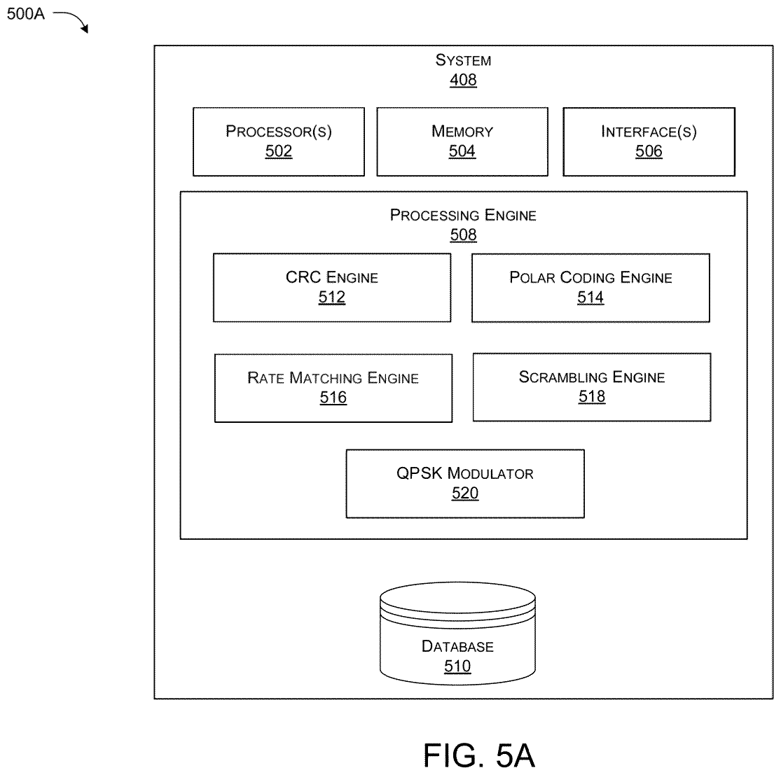

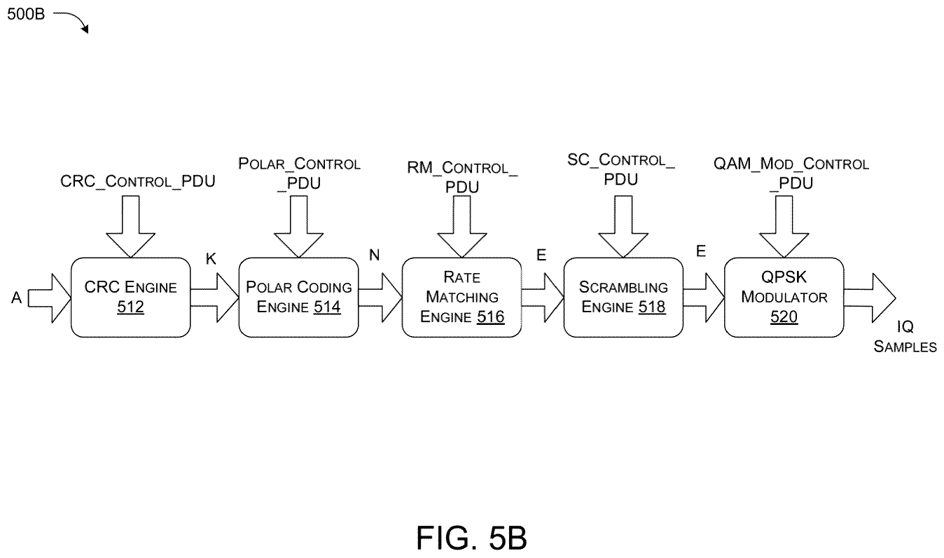

FIGS. 5A and 5B illustrate exemplary block diagrams (500A, 500B) of the proposed system (408), and the sub-blocks of a system processing engine (508), respectively, in accordance with embodiments of the present disclosure.

With respect to FIG. 5A, the system (408) may include one or more processors (502). The one or more processors (502) may be implemented as one or more microprocessors, microcomputers, microcontrollers, digital signal processors, central processing units, logic circuitries, and/or any devices that manipulate data based on operational instructions. Among other capabilities, the one or more processor(s) (502) may be configured to fetch and execute computer-readable instructions stored in a memory (504) of the system (408). The memory (504) may store one or more computer-readable instructions or routines, which may be fetched and executed to create or share the data units over a network service. The memory (504) may include any non-transitory storage device including, for example, volatile memory such as Random-Access Memory (RAM), or non-volatile memory such as Erasable Programmable Read-Only Memory (EPROM), flash memory, and the like.

In an embodiment, the system (408) may also include an interface(s) (506). The interface(s) (506) may comprise a variety of interfaces, for example, a variety of interfaces, for example, interfaces for data input and output devices, referred to as I/O devices, storage devices, and the like. The interface(s) (506) may facilitate communication of the system (408) with various devices coupled to it. The interface(s) (506) may also provide a communication pathway for one or more components of the system (408). Examples of such components include, but are not limited to, processing engine(s) (508) and a database (510).

In an embodiment, the processing engine(s) (508) may be implemented as a combination of hardware and programming (for example, programmable instructions) to implement one or more functionalities of the processing engine(s) (508). In examples described herein, such combinations of hardware and programming may be implemented in several different ways. For example, the programming for the processing engine(s) (508) may be processor executable instructions stored on a non-transitory machine-readable storage medium and the hardware for the one or more processors (502) may comprise a processing resource (for example, one or more processors), to execute such instructions. In the present examples, the machine-readable storage medium may store instructions that, when executed by the processing resource, implement the processing engine(s) (508). In such examples, the system (408) may comprise the machine-readable storage medium storing the instructions and the processing resource to execute the instructions, or the machine-readable storage medium may be separate but accessible to the system (408) and the processing resource. In other examples, the processing engine(s) (508) may be implemented by an electronic circuitry.

In an exemplary embodiment, with reference to FIGS. 5A and 5B, the processing engine(s) (508) may include one or more engines selected from any of a CRC engine (512), a polar coding engine (514), a rate matching engine (516), a scrambling engine (518), and a QPSK modulator (520). It may be appreciated that the CRC engine (512) may be interchangeably referred to as a CRC block.

In an embodiment, the database (510) may comprise data that may be either stored or generated as a result of functionalities implemented by any of the components of the processor(s) (502) or the processing engine(s) (508) or the system (408).

As per 3GPP, both the PBCH and PDCCH PDUs use same G_{CRC24C}(D) generator polynomial. Input A bits from L2 having BCH PDU or DCI PDU may be passed through the CRC block (512), where L=24 number of parity bits generated by dividing an entire incoming bit stream with G_{CRC24C}(D) polynomial, and may be appended to A incoming bit stream resulting into K=A+L number of bit stream output. The CRC block (512) may be implemented using a Linear Feedback Shift Register (LFSR). While BCH payload size A is fixed at 32 bits, DCI payload size may range from 12 to 140 bits. Further, ‘A’ input bit stream may be appended with L=24 bits before passing through the LFSR. As per 3GPP, for PBCH processing, 24 zeroes may be appended, whereas for PDCCH, 24 ones may be appended.

Hence, the CRC block (512) may be passed with following ‘CRC_Control_PDU’ from L2:

Struct CRC_Control_PDU
{
Uint8 A; //LSB 8 bits carrying Input Payload Size A
Uint8 Channel Indicator; // 0 →BCH PDU and 1 → DCI PDU
};

For processing each PBCH/PDCCH PDU, the CRC block (512) may be provided with above control data from the L2. The CRC block (512) may determine PDU length, and distinguish between PDUs corresponding to the PDCCH and PBCH chain for appending 24 zeroes, when the channel indicator field in CRC_Control_PDU structure is set to ‘0’ indicating BCH PDU, whereas for appending 24 ones, when channel indicator field in CRC_Control PDU structure is set to ‘1’ indicating DCI PDU.

CRC added bit stream of length K may be then provided to a polar coding engine (514). The polar coding engine (514) may be interchangeably referred to as a polar coding block for channel coding. The polar coding block (514) may include an interleaver or interleaving stage as per the 3GPP, before actual polar encoding. 3GPP necessitates that the CRC added BCH PDU has to pass through the interleaver or interleaving stage, whereas the DCI PDU has to bypass the interleaver or interleaving stage, and non-interleaved data may be polar encoded.

The polar coding block (514) may take K bits which is derived by a formula, K=A+24 as input, and provide N bit of output code-word where N=2\hat{ }n (n may be {5, 6, 7, 8, 9}). The value of ‘n’ may be determined using a rate matched output length ‘E’ and polar input bit length ‘K’ as per the 3GPP. Further, ‘E’ may be derived using following:

‘E’ = 108 * Aggregation Level // for PDCCH PDU
or,
‘E’ = 864 //for PBCH PDU

Aggregation level for the PDCCH PDU may be readily available with L2 and hence the same may be provided to the polar coding block (514). However, there are no aggregation levels defined for the PBCH. The aggregation levels for the PBCH may be set to ‘8’ while providing to the polar coding block (514) for processing the PBCH PDU so that ‘E’ may be derived by the block (514) as 864. Hence, the polar coding block (514) may be provided by L2 with following “Polar_Control_PDU”:

```
Struct Polar_Control_PDU
{
  Uint8 A; // Input Payload Size A
  Uint8 Channel Indicator; // 0 → BCH PDU and 1 →DCI PDU
  Uint8 Aggregation Level; // 1, 2, 4, 8, 16 for PDCCH PDU; 8 for
  PBCH PDU
};
```

Payload size field ‘A’ of the polar control PDU may be used to derive K by the polar coding block (514). The polar coding block (514) may bypass the interleaver stage when the channel indicator received is ‘1’ indicating PDCCH PDU, whereas PBCH may pass through the interleaver stage. Further, aggregation level may be used to derive ‘E’ by the polar coding block (514). ‘E’ along with ‘A’ may further be used to calculate ‘N’. Aggregation level field may be mandatorily set to ‘8’ for the PBCH.

In an embodiment, the rate matching engine (516) may be interchangeably referred to as a rate matching block. The rate matching block (516) may perform rate matching for the PBCH which is simpler as compared to the PDCCH PDU. For the PBCH, rate matching input size ‘N’ may be fixed at 512, and rate matching output size ‘E’ may be fixed at 864 with only repetitions condition being used. The PDCCH, on the other hand, may have 5 possible values of N i.e., N={32, 64, 128, 256, and 512}. Similarly, ‘E’ may also have 5 possible values 108, 216, 432, 864, and 1728 corresponding to the aggregation levels 1, 2, 4, 8, and 16, respectively. Depending on the N and the E, the rate matching may either use shortening, puncturing, or repetition for bit selection.

The PBCH rate matching may be same as one of the cases valid for the PDCCH rate matching. Thus, the PDCCH rate matching block may be used for the PBCH processing. In addition, by providing A=32 and aggregation level=8, the rate matching block (516) may derive ‘N’=512 and ‘E’=864 may be required for PDCCH PDU thereafter as per 3GPP. Thus, following rate matching (RM) control PDU may be required from L2 to the rate matching block (516):

```
Struct RM_Control_PDU
{
  Uint8 A; //LSB 8 bits carrying Input Payload Size A
  Uint8 Aggregation Level; // 1, 2, 4, 8, 16 for PDCCH PDU; 8 for
  PBCH PDU
};
```

Further, a scrambling engine (518) may be interchangeably referred to as a scrambling block. The scrambling block (518) may perform bitwise Exclusive OR (XOR) operation on the rate matched ‘E’ bits with same length of pseudo-random (PN) gold sequence. Each PN sequence may be characterized by a seed value. The seed value or ‘cᵢₙᵢₜ’ as defined in 3GPP varies for the PBCH and the PDCCH.

As per 3GPP, for the PDCCH:

$${C}_{init} = ( {n}_{RNTI} \cdot {2}^{16} + {n}_{ID} ) mod {2}^{31}$$

Where, for a UE-specific search space as defined in 3GPP, n_{ID}ε{0, 1, . . . , 65535} equals the higher layer parameter pdcch-DMRS-ScramblingID if configured,

n_{ID}=N_{ID}^{cell} otherwise

And where,
n_{RNTI} is given by the C-RNTI for a PDCCH in a UE-specific search space if the higher-layer parameter pdcch-DMRS-ScramblingID is configured, and
n_{RNTI}=0 otherwise,

### Whereas for the PBCH:

Cᵢₙᵢₜ=N_{ID}^{cell}

N_{ID}^{cell} is the Physical Cell Identity (PCI) of a cell which may range from 0 to 1007. Additionally, PN sequence generation for PBCH may also be dependent on three LSB bits of SSB index. In order to generalize the scrambling block (518) for both PBCH and PDCCH processing, C_{ID}^{init} calculation formula given for the PDCCH may be used. The same Cᵢₙᵢₜ calculation formula may be used for the PBCH as a special case by providing n_{RNTI} as ‘0’ and n_{ID} as N_{ID}^{cell}.

Additionally, a scrambling sequence selection based on 3 LSBs of SSB index may be implemented. For PDCCH, the SSB index may be expected to be provided by L2 as ‘0’. Further, aggregation level parameter may be used to derive ‘E’ by the scrambling block (518) where the aggregation level is provided with value 8 for the PBCH PDU.

Following is the SC Control PDU expected by the scrambling block (518) from L2:

```
Struct SC_Control_PDU
{
  Uint16 n_{ID}; //PDCCH DMRS Scrambling ID or PCI
  Uint16 n_{RNTI}; // ‘C-RNTI’ for UE specific PDCCH else ‘0’
  Uint8 Aggregation Level; //1, 2, 4, 8, 16 for PDCCH PDU; 8 for PBCH
  PDU
  Uint8 SSB Index; //3 LSB bits of the SSB Index for PBCH; ‘0’ for
  PDCCH
};
```

Both the PBCH and the PDCCH may be further QPSK modulated using a same QPSK modulator (520), which requires only ‘E’ for determining the input bit length and corresponding number of output quadrature (IQ) samples. As is explained above, ‘E’ may be derived by the QPSK modulator (520) from the aggregation level field. Following is the QAM Mod Control PDU expected by the QPSK modulator (520) from L2:

```
Struct QAM Mod_Control_PDU
{
  Uint8 Aggregation Level; //1, 2, 4, 8, 16 for PDCCH PDU; 8 for PBCH
  PDU
};
```

Therefore, all 5 sub-blocks—the CRC block (512), the polar coding block (514), the rate matching block (516), the scrambling block (518), and the QPSK modulator (520), and their control parameters may be designed in such a way that a same set of sub-blocks may support processing of both PBCH and PDCCH PDU. Reuse of the same sub-blocks may ensure that resource utilization (such as Block RAMs (BRAMs), lookup tables (LUTs), Flip Flops (FFs), and digital signal processors (DSPs) in an Field Programmable Gate Arrays (FPGA) chip) is significantly reduced compared to conventional designs where both the PBCH and the PDCCH have their separate processing chain. As a common processing chain processes both the PBCH and the PDCCH PDUs, both the chains may have to operate in a time-multiplexed manner. Hence, the processing time of the PBCH and all the PDCCH PDUs combined may be lesser than permissible 1 slot timing budget.

The present disclosure is not only limited to presented exemplary embodiment of implementing the PBCH and PDCCH transmitter in the FPGA chip, but may be equally applicable to implementation in any other platform such as hardware accelerators, enhanced-application-specific integrated circuit (eASIC), DSP, software defined radio, etc., wherever PBCH and PDCCH chains are implemented wholly or partially in a hardware having hardware resource footprint. In addition, the present disclosure may also equally applicable for implementation of a Bit Rate Processing chain of a unified PBCH and PDCCH receiver.

In an embodiment, all sub-blocks highlighted in the above exemplary embodiment may have its reciprocal counterparts in the receiver chain in reverse order of execution, namely QAM demodulator, descrambler, de-rate matching, polar decoding, and CRC check. All control parameters and sub-block implementations given in this exemplary document may be valid for the implementation of Bit Rate Processing chain of the unified PBCH and PDCCH receiver.

In the receiver chain, a UE (404) may receive a plurality of modulated bits of control data from a system (408). The UE (404) may demodulate the plurality of received bits using the QAM demodulator. The UE (404) may perform descrambling operation on the plurality of demodulated bits using the descrambler. Further, the UE (404) may perform de-rate matching of the plurality of demodulated bits based on outputs of the descrambling operation using de-rate matching.

In an embodiment, the UE (404) may determine if the plurality of de-rate matched bits corresponds to the BCH data or the DCI data based on one or more control parameters corresponding to one or more control channels. The UE (404) may perform de-interleave the plurality of de-rate matched bits if the plurality of received bits corresponds to the BCH data, and may bypass de-interleaving of the plurality of de-rate matched bits if the plurality of received bits corresponds to the DCI data. The UE (404) may decode the plurality of de-rate matched bits based on the determination using the polar decoding approach, and provide the plurality of decoded bits to a cyclic redundancy check (CRC) engine (512).

The above-mentioned method of using unified PBCH PDCCH processing chain may be implemented in a system that uses a single FPGA chip which has limited number of FPGA resources (BRAMs, LUTs, FFs, and DSPs). This optimized design of reusing the same sub-blocks may ensure that the resource utilization is considerably less as compared to conventional designs where both the PBCH and the PDCCH have their separate processing chain. It may be appreciated that the resources saved are critical for development of other Layer 1 downlink and uplink chains.

Table 1 depicts comparative resource utilization numbers between the conventional standalone PBCH and PDCCH chains and the unified PBCH PDCCH chain. As is shown, the unified PBCH PDCCH chain has been crucial in resource saving of 50% or more:

TABLE 1

| | | | Standalone | | Resource |
|---|---|---|---|---|---|
| | | | PBCH | Unified | Savings |
| | | Standalone | (A) + | PBCH | (C − |
| | Standalone | PDCCH | Standalone | PDCCH | (A + B))/ |
| | PBCH (A) | (B) | PDCCH (B) | (C) | C |
| LUT | 10569 | 10723 | 21292 | 10549 | 50% |
| FF | 8510 | 8720 | 17230 | 8627 | 50% |
| BRAM | 11 | 8 | 19 | 5 | 74% |
| DSP | 2 | 1 | 3 | 1 | 67% |

As shown in Table 1, processing time of the PBCH PDUs is less than 10 us and there can be maximum of 2 PBCH PDUs in a slot of 500 us. The PDCCH PDU count per slot may be maximum 40 considering 16 UEs/transmission time interval (TTI), whereas processing time is again close to 10 us only for each PDU. Hence, the total processing time in conventional design that uses separate PBCH and PDCCH chain may be go up to 400 us (maximum (total PDCCH processing latency, total PBCH processing latency)). Whereas, the same may be 420 us for unified PBCH PDCCH design where both PDUs may be processed sequentially. Hence, the proposed system and method shows better performance with respect to 500 us processing latency budget. Hence, benefit of resource saving brought in by the unified design exceeds overwhelmingly without breaching the designated timing budget of 1 slot i.e., 500 us.

Although FIGS. 5A and 5B show exemplary components of the system (408), in other embodiments, the system (408) may include fewer components, different components, differently arranged components, or additional functional components than depicted in FIGS. 5A and 5B. Additionally, or alternatively, one or more components of the system (408) may perform functions described as being performed by one or more other components of the system (408).

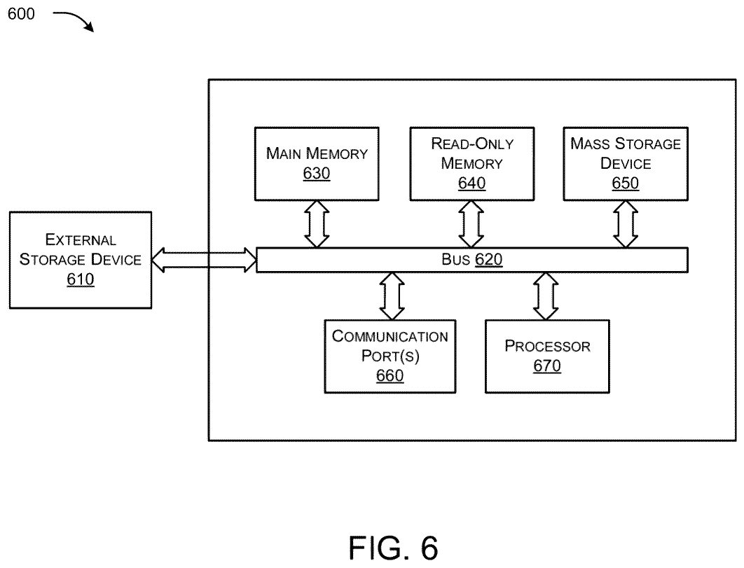

FIG. 6 illustrates an exemplary computer system (600) in which or with which embodiments of the present disclosure may be utilized, in accordance with embodiments of the present disclosure.

As shown in FIG. 6, the computer system (600) may include an external storage device (610), a bus (620), a main memory (630), a read only memory (640), a mass storage device (650), a communication port (660), and a processor (670).

A person skilled in the art will appreciate that the computer system (600) may include more than one processor and communication ports. The processor (670) may include various modules associated with embodiments of the present disclosure.

In an embodiment, the communication port (660) may be any of an RS-232 port for use with a modem-based dialup connection, a 10/100 Ethernet port, a Gigabit or 10 Gigabit port using copper or fiber, a serial port, a parallel port, or other existing or future ports. The communication port (660) may be chosen depending on a network, such a Local Area Network (LAN), Wide Area Network (WAN), or any network to which the computer system (600) connects.

In an embodiment, the memory (630) may be a Random Access Memory (RAM), or any other dynamic storage device commonly known in the art. The read-only memory (640) may be any static storage device(s) e.g., but not limited to, a Programmable Read Only Memory (PROM) chips for storing static information e.g., start-up or Basic Input/Output system (BIOS) instructions for the processor (670).

In an embodiment, the mass storage (650) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), one or more optical discs, Redundant Array of Independent Disks (RAID) storage, e.g., an array of disks (e.g., SATA arrays).

In an embodiment, the bus (620) communicatively couples the processor(s) (670) with the other memory, storage, and communication blocks. The bus (620) may be, e.g., a Peripheral Component Interconnect (PCI)/PCI Extended (PCI-X) bus, Small Computer System Interface (SCSI), USB or the like, for connecting expansion cards, drives, and other subsystems as well as other buses, such a front side bus (FSB), which connects the processor (670) to computer system (600).

Optionally, operator and administrative interfaces, e.g., a display, keyboard, joystick, and a cursor control device, may also be coupled to the bus (620) to support direct operator interaction with the computer system (600). Other operator and administrative interfaces may be provided through network connections connected through the communication port (660). Components described above are meant only to exemplify various possibilities. In no way should the aforementioned exemplary computer system (600) limit the scope of the present disclosure.

While the foregoing describes various embodiments of the invention, other and further embodiments of the invention may be devised without departing from the basic scope thereof. The scope of the invention is determined by the claims that follow. The invention is not limited to the described embodiments, versions or examples, which are included to enable a person having ordinary skill in the art to make and use the invention when combined with information and knowledge available to the person having ordinary skill in the art.

### ADVANTAGES OF THE PRESENT DISCLOSURE

The present disclosure provides a system and a method that implements a unified common processing chain where each physical layer 1 (L1) sub-block is designed to process both Physical Broadcast Channel (PBCH) and Physical Downlink Control Channel (PDCCH) Packet Data Units (PDU) seamlessly.

The present disclosure provides a system and a method to modify control data received by L1 sub-blocks from a Layer 2 (L2) over a L1-L2 interface.

The present disclosure provides a system and a method to optimize resource utilization during channel coding.

The present disclosure provides a system and a method to modify control parameters in such a way that a same set of sub-blocks may support processing of both the PBCH and PDCCH PDUs, thereby ensuring resource utilization.

The present disclosure provides a system and a method to reduce processing time of the PBCH PDUs and the PDCCH PDUs.

We claim:

1. A system (408) for processing data in one or more control channels using a unified processing chain, the system (408) comprising:
one or more processors (502); and
a memory (504) operatively coupled to the one or more processors (502), wherein the memory (504) comprises processor-executable instructions, which on execution, cause the one or more processors (502) to:
provide control data comprising a plurality of bits from the one or more control channels to a cyclic redundancy check (CRC) engine (512);
determine if the plurality of bits of the control data corresponds to a broadcast channel (BCH) data or a downlink control information (DCI) data based on one or more control parameters corresponding to the one or more control channels;
perform one of:
interleave the plurality of bits if the plurality of bits corresponds to the BCH data; and
bypass interleaving of the plurality of bits if the plurality of bits corresponds to the DCI data;
perform rate matching of the plurality of bits to ensure that the plurality of bits corresponds to a capacity of the one or more control channels based on the determination;
determine a length of the plurality of rate matched bits by setting an aggregation level for the one or more control channels;
perform scrambling operation on the plurality of rate matched bits based on the length of the plurality of rate matched bits; and
modulate the plurality of rate matched bits based on outputs of the scrambling operation.

2. The system (408) as claimed in claim 1, wherein the one or more control channels are Physical Broadcast Channel (PBCH) and Physical Downlink Control Channel (PDCCH).

3. The system (408) as claimed in claim 1, wherein the one or more control parameters corresponding to the one or more control channels comprise at least one of: a payload size field and a channel indicator field.

4. The system (408) as claimed in claim 1, wherein the memory (504) comprises processor-executable instructions, which on execution, cause the one or more processors (502) to determine a length of the control data, and distinguish the control data corresponding to each control channel of the one or more control channels for appending correct bit sequence in the CRC engine (512) based on a channel indicator field.

5. The system (408) as claimed in claim 4, wherein the one or more processors (502) are to append 24 zeroes to an incoming payload of the control data if the channel indicator field is set to 0 indicating the BCH data, and append 24 ones to the incoming payload of the control data if the channel indicator field is set to 1 indicating the DCI data.

6. The system (408) as claimed in claim 1, wherein the memory (504) comprises processor-executable instructions, which on execution, cause the one or more processors (502) to encode the plurality of bits of the control data prior to performing the rate matching.

7. The system (408) as claimed in claim 1, wherein the one or more processors (502) are to perform the rate matching of the plurality of bits based on a payload size of the control data and the aggregation level of the one or more control channels, and wherein the aggregation level for the BCH data is set to 8.

8. The system (408) as claimed in claim 1, wherein the one or more processors (502) are to perform the scrambling operation on the plurality of rate matched bits using at least one of: a Radio Network Temporary Identifier (RNTI), a Physical Cell Identity (PCI), a Synchronization Signal Block (SSB) index, and the aggregation level.

9. The system (408) as claimed in claim 1, wherein the one or more processors (502) are to perform the scrambling operation on the plurality of rate matched bits by determining a pseudo-random (PN) sequence length of the plurality of rate matched bits using the aggregation level.

10. A method for processing data in one or more control channels using a unified processing chain, the method comprising:
providing, by a processor (502) associated with a system (408), control data comprising a plurality of bits from the one or more control channels to a cyclic redundancy check (CRC) engine (512);
determining, by the processor (502), if the plurality of bits of the control data corresponds to a broadcast channel (BCH) data or a downlink control information (DCI) data based on one or more control parameter corresponding to the one or more control channels;
performing, by the processor (502), one of:
interleaving the plurality of bits if the plurality of bits corresponds to the BCH data; and
bypassing interleaving of the plurality of bits if the plurality of bits corresponds to the DCI data;
performing, by the processor (502), rate matching of the plurality of bits to ensure that the plurality of bits corresponds to a capacity of the one or more control channels based on the determination;
determining, by the processor (502), a length of the plurality of rate matched bits by setting an aggregation level for the one or more control channels;
performing, by the processor (502), scrambling operation on the plurality of rate matched bits based on the length of the plurality of rate matched bits; and
modulating, by the processor (502), the one or more channels based on outputs of the scrambling operation.

11. The method as claimed in claim 10, wherein the one or more control parameters corresponding to the one or more control channels comprise at least one of: a payload size field and a channel indicator field.

12. The method as claimed in claim 10, comprising determining, by the processor (502), a length of the control data, and distinguishing, by the processor (502), the control data corresponding to each control channel of the one or more control channels for appending correct bit sequence in the CRC engine (512) based on a channel indicator field.

13. The method as claimed in claim 12, comprising appending, by the processor (502), 24 zeroes to an incoming payload of the control data if the channel indicator field is set to 0 indicating the BCH data, and appending, by the processor (502), 24 ones to the incoming payload of the control data if the channel indicator field is set to 1 indicating the DCI data.

14. The method as claimed in claim 10, comprising encoding, by the processor (502), the plurality of bits of the control data prior to performing the rate matching.

15. The method as claimed in claim 10, wherein performing, by the processor (502), the rate matching of the plurality of bits is based on a payload size of the control data and the aggregation level of the one or more control channels, and wherein the aggregation level for the BCH data is set to 8.

16. The method as claimed in claim 10, wherein performing, by the processor (502), the scrambling operation on the plurality of rate matched bits comprises determining a pseudo-random (PN) sequence length of the plurality of rate matched bits using the aggregation level.

17. A user equipment (404), comprising:
one or more processors; and
a memory operatively coupled to the one or more processors, wherein the memory comprises processor-executable instructions, which on execution, cause the one or more processors to: receive a plurality of modulated bits of control data from a system (408);
demodulate the plurality of received bits;
perform descrambling operation on the plurality of demodulated bits;
perform de-rate matching of the plurality of demodulated bits based on outputs of the descrambling operation;
determine if the plurality of de-rate matched bits corresponds to a broadcast channel (BCH) data or a downlink control information (DCI) data based on one or more control parameters corresponding to one or more control channels;
perform one of:
de-interleave the plurality of de-rate matched bits if the plurality of received bits corresponds to the BCH data; and
bypass de-interleaving of the plurality of de-rate matched bits if the plurality of received bits corresponds to the DCI data;
decode the plurality of de-rate matched bits based on the determination; and
provide the plurality of decoded bits to a cyclic redundancy check (CRC) engine (512).

18. A non-transitory computer-readable medium comprising processor-executable instructions that cause a processor to:
provide control data comprising a plurality of bits from one or more control channels to a cyclic redundancy check (CRC) engine (512);
determine if the plurality of bits of the control data corresponds to a broadcast channel (BCH) data or a downlink control information (DCI) data based on one or more control parameters corresponding to the one or more control channels;
perform one of:
interleave the plurality of bits if the plurality of bits corresponds to the BCH data; and
bypass interleaving of the plurality of bits if the plurality of bits corresponds to the DCI data;
perform rate matching of the plurality of bits to ensure that the plurality of bits corresponds to a capacity of the one or more control channels based on the determination;
determine a length of the plurality of rate matched bits by setting an aggregation level for the one or more control channels;
perform scrambling operation on the plurality of rate matched bits based on the length of the plurality of rate matched bits; and
modulate the plurality of rate matched bits based on outputs of the scrambling operation.
